(19) United States
(12) Patent Application Publication
(10) Pub. No.: US 2021/0063534 A1
(43) Pub. Date: Mar. 4, 2021

(54) REAL-TIME CALIBRATION OF A PHASED ARRAY ANTENNA INTEGRATED IN A BEAM STEERING RADAR

(71) Applicant: Metawave Corporation, Carlsbad, CA (US)

(72) Inventor: Soren Shams, Irvine, CA (US)

(21) Appl. No.: 17/006,701

(22) Filed: Aug. 28, 2020

Related U.S. Application Data
(60) Provisional application No. 62/894,638, filed on Aug. 30, 2019.

(51) Int. Cl. G01S 7/40; H01Q 3/36; H03F 3/19

(52) U.S. Cl. CPC G01S 7/4008; H01Q 3/36; G01S 13/931; G01S 2007/4013; H03F 3/19

(57) ABSTRACT

Examples disclosed herein relate to a system for real-time calibration of a phased array antenna integrated in a beam steering radar. The system includes a calibration unit for injecting a calibration signal to the phased array antenna during operation of the beam steering radar, the calibration signal at a frequency different than a frequency of operation of the beam steering radar, a plurality of transmit calibration couplers for receiving the injected signal, the transmit calibration couplers connected to a plurality of amplifiers and phase shifters in the phased array antenna to generate a phase shifted and amplified signal, and a plurality of receive calibration couplers connected to the plurality of phase shifters for transmitting the phase shifted and amplified signal to the calibration unit for measurement.

### CROSS-REFERENCE TO RELATED APPLICATIONS

This application claims priority from U.S. Provisional Application No. 62/894,638, filed on Aug. 30, 2019, and incorporated by reference in its entirety.

### FIELD OF THE INVENTION

The present invention relates to real-time calibration of a phased array antenna integrated in a beam steering radar.

### BACKGROUND

Phased array antennas form a radiation pattern by combining signals from a number of antenna elements and controlling the phase and amplitude of each element. The antenna or radiating elements are arranged in an array or sub-arrays and typically include patches in a patch antenna configuration, a dipole, or a magnetic loop, among others. The relative phase between each radiating element can be fixed or adjusted by employing phase shifters coupled to each element. The direction of the beam generated by the antenna is controlled by changing the phase of the individual elements. Amplifiers coupled between the radiating elements and the phase shifters provide amplitude control of the radiating beam. The ability to control amplitude and phase precisely depends on an effective calibration of the antenna elements, phase shifters and amplifiers to compensate for any variances and signals perturbations due to manufacturing, hardware issues, temperature, environment, and other effects.

Antenna calibration consists of determining near-field and far-field radiation patterns for the antenna under different operating parameters and conditions. The near-field radiation pattern is the pattern emitted in the region immediately surrounding the antenna and within a distance of a wavelength or less. Anything beyond the near-field is deemed to be far-field. The far-field radiation pattern depends upon the distance to the antenna. Conventional near-field and far-field calibration can be performed with various measurement systems and calibration probes that are commercially available and suitable for different scenarios, applications and certain frequency bands. Each element in the phased array antenna as well as the phase shifters and amplifiers need to be calibrated to correct for phase and amplitude variations. The calibration of phased array antennas that are integrated in complex systems used in millimeter wave applications beyond 70 GHz is particularly challenging.

Therefore, there is a need for a system and methods for calibrating phased array antennas, and in particular phased array antennas that can be integrated in complex systems used in millimeter wave applications.

### BRIEF DESCRIPTION OF THE DRAWINGS

The present application may be more fully appreciated in connection with the following detailed description taken in conjunction with the accompanying drawings, which are not drawn to scale and in which like reference characters refer to like parts throughout, and wherein:

FIG. 1 illustrates an example environment in which a beam steering radar in an autonomous vehicle is used to detect and identify objects;

FIG. 2 is a schematic diagram of an autonomous driving system for an autonomous vehicle in accordance with various examples;

FIG. 3 illustrates a schematic diagram of a beam steering radar system in accordance with various examples;

FIG. 4 illustrates the antenna elements of the receive and guard antennas of FIG. 3 in more detail;

FIG. 5 is a schematic diagram for real-time calibration of transmit and receive antennas in the radar module of FIG. 3 in accordance with various examples;

FIG. 6 is another schematic diagram for real-time calibration of transmit and receive antennas in the radar module of FIG. 3 in accordance with various examples;

FIG. 7 is a schematic diagram for real-time calibration of transmit and receive antennas in the radar module of FIG. 3 with the addition of a calibration transceiver in accordance with various examples; and

FIG. 8 is a flowchart illustrating a calibration process for a transmit or receive antenna in accordance to various examples.

### DETAILED DESCRIPTION

The real-time calibration of a phased array antenna integrated in a beam steering radar is disclosed. The phased array antenna generates a narrow, directed beam that can be steered to any angle (i.e., from 0° to 360°, from 0° to 90°, from 0° to 180°, from 0° to 270°, from 0° to −90°, from 0° to −180°, from 0° to −270°) across a Field of View (“FoV”) to detect objects. Beam steering is accomplished with the use of phase shifters coupled to the antenna elements. Power and low noise amplifiers adjust the gain of the antenna to provide beams for both short (e.g., <250 m, <200 m, <150 m, <100 m, <50 m, <25 m, <10 m, <5 m, or <1 m,) and long ranges (e.g., >250 m, >500 m, >1 km, or >10 km). The ability to control phase and amplitude precisely depends on an effective calibration of the antenna elements to compensate for any variances and signal perturbations due to manufacturing, hardware issues, temperature, environmental, and other effects. In various examples, amplitude and phase calibration of the antenna elements are performed in real-time with the antenna built-in or integrated in a complex radar module. While the examples detailed herein apply to real-time calibration schemes, can it be performed in any other manners, such as on a periodic schedule, on intervals determined by triggering events, such as on a long time between target detections that may indicate the radar is not properly calibrated, or in by non real-time means. Some triggering events may be on car start, on car stop, on scheduled delays, on scheduled events, or triggered manually by the operator. Some triggers will indicate that the calibration is done in parallel with radar operation so as not to interrupt driving, such as performing calibration on ignition. Calibration on turning off the engine may prolong the power down cycle. A good time for calibration is on detection of an operational failure or maintenance due indicator, as this may impact operation of the radar unit as well.

The on-board calibration capability of the present inventions is in contrast to traditional, stand-alone antenna calibration mechanisms in which the antenna is calibrated individually and apart from other modules. The calibration of the phased array antenna is performed with the use of couplers integrated in the radar module circuit board without significantly disrupting the design, manufacture, operation, or performance of the radar board. As automotive systems gain in complexity and capability, there is more dependence on the sensor systems generally and specifically the radar system. This dependency only emphasizes the use of on-board calibration systems that enable a vehicle to continue operation without significant down time, such as at a dealership or repair shop.

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, the subject technology is not limited to the specific details set forth herein and may be practiced using one or more implementations. In one or more instances, structures and components are shown in block diagram form in order to avoid obscuring the concepts of the subject technology. In other instances, well-known methods and structures may not be described in detail to avoid unnecessarily obscuring the description of the examples. Also, the examples may be used in combination with each other.

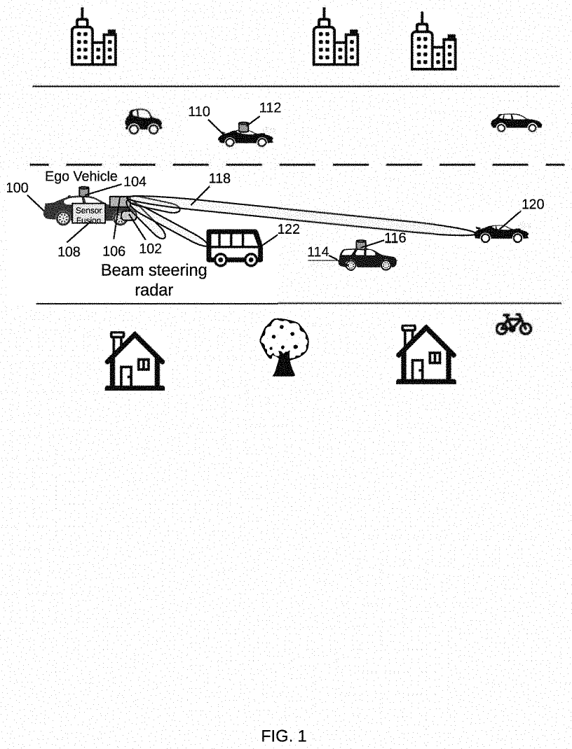

FIG. 1 illustrates an example environment in which a beam steering radar 106 in an autonomous vehicle 100, labeled as an ego vehicle, is used to detect and identify objects, such as vehicles 110, 112, 114, 120 and bus 122, as well as buildings, houses, trees and other obstacles that may be in the path of a vehicle. Ego vehicle 100 is an autonomous vehicle with a beam steering radar system 106 for transmitting a radar signal to scan a FoV or specific area. As described in more detail below, the radar signal is transmitted according to a set of scan parameters that can be adjusted to result in multiple transmission beams 118. The scan parameters may include, among others, the total angle of the scanned area defining the FoV, the beam width or the scan angle of each incremental transmission beam, the number of chirps in the radar signal, the chirp time, the chirp segment time, the chirp slope, and so on. The entire FoV or a portion of it can be scanned by a compilation of such transmission beams 118, which may be in successive adjacent scan positions or in a specific or random order. In some implementations, the term FoV is used herein in reference to the radar transmissions and does not imply an optical FoV with unobstructed views. The scan parameters may also indicate the time interval between these incremental transmission beams, as well as start and stop angle positions for a full or partial scan.

As illustrated in FIG. 1, other vehicles may have sensor units in place as well, such as sensor 116 on vehicle 114, sensor 112 on vehicle 110, which may be able to detect vehicle 100. This capability may enable smarter vehicle to vehicle (V2V) communications improving safety. These sensors may also prove beneficial in calibration of the radar 106 as providing verifying information and other signals that help align and correct any errors in the radar 106 operation.

In various examples, the ego vehicle 100 may have perception sensors, such as camera 102 and lidar 104. In some implementations, the perception sensors are can be used in augmenting the object detection capabilities of the beam steering radar 106. Camera sensor 102 may be used to detect visible objects and conditions and to assist in the performance of various functions. The lidar sensor 104 can also be used to detect objects and provide this information to adjust control of the vehicle. Example information may include any information related to, but not limited to congestion on a highway, road conditions, and other conditions that would impact the sensors, actions or operations of the vehicle. Camera sensors are currently used in Advanced Driver Assistance Systems (“ADAS”) to assist drivers in driving functions such as parking (e.g., in rear view cameras). Cameras are able to capture texture, color and contrast information at a high level of detail, but similar to the human eye, they are susceptible to adverse weather conditions and variations in lighting. Camera 102 may have a high resolution but cannot resolve objects beyond 50 meters.

Lidar sensors typically measure the distance to an object by calculating the time taken by a pulse of light to travel to an object and back to the sensor. When positioned on top of a vehicle, a lidar sensor is able to provide a 360° 3D view of the surrounding environment. Other approaches may use several lidars at different locations around the vehicle to provide the full 360° view. However, lidar sensors such as lidar 104 are still prohibitively expensive, bulky in size, sensitive to weather conditions and are limited to short ranges (typically <150-200 meters). Radars, on the other hand, have been used in vehicles for many years and operate in all-weather conditions. Radars also use far less processing than the other types of sensors and have the advantage of detecting objects behind obstacles and determining the speed of moving objects. When it comes to resolution, lidars' laser beams are focused on small areas, have a smaller wavelength than RF signals, and are able to achieve around 0.25 degrees of resolution for a given FoV.

In various examples and as described in more detail below, the beam steering radar 106 is capable of providing a 360° true 3D vision and human-like interpretation of the ego vehicle's path and surrounding environment. The beam steering radar 106 is capable of shaping and steering RF beams in all directions in a 360° FoV with at least one beam steering antenna and recognize objects quickly and with a high degree of accuracy over a long range of around 300 meters or more. The short range capabilities of camera 102 and lidar 104 along with the long range capabilities of radar 106 enable a sensor fusion module 108 in ego vehicle 100 to enhance its object detection and identification.

As illustrated in FIG. 1, the beam steering radar 106 is capable of detecting both the vehicle 120 at a far range (e.g., >250 m) as well as the bus 122 at a short range (e.g., <100 m). Detecting both in a short amount of time and with enough range and velocity resolution is imperative for full autonomy of driving functions of the ego vehicle. The beam steering radar 106 has an adjustable long range radar (“LRR”) mode that enables the detection of long range objects in a very short time to then focus on obtaining finer velocity resolution for the detected vehicles. In accordance with various embodiments, the beam steering radar 106 is capable of time-alternatively reconfiguring between LRR and short-range radar (“SRR”) modes, which means that the radar may alternate between LRR operation and SRR operation at different times. The SRR mode enables a wide beam with lower gain but is able to make quick decisions to avoid an accident, assist in parking and downtown travel, and capture information about a broad area of the environment. The LRR mode enables a narrow, directed beam and long distance, having high gain; this is powerful for high speed applications, and where longer processing time allows for greater reliability. Excessive dwell time for each beam position may cause blind zones, and the adjustable LRR mode ensures that fast object detection can occur at long range while maintaining the antenna gain, transmit power and desired SNR for the radar operation.

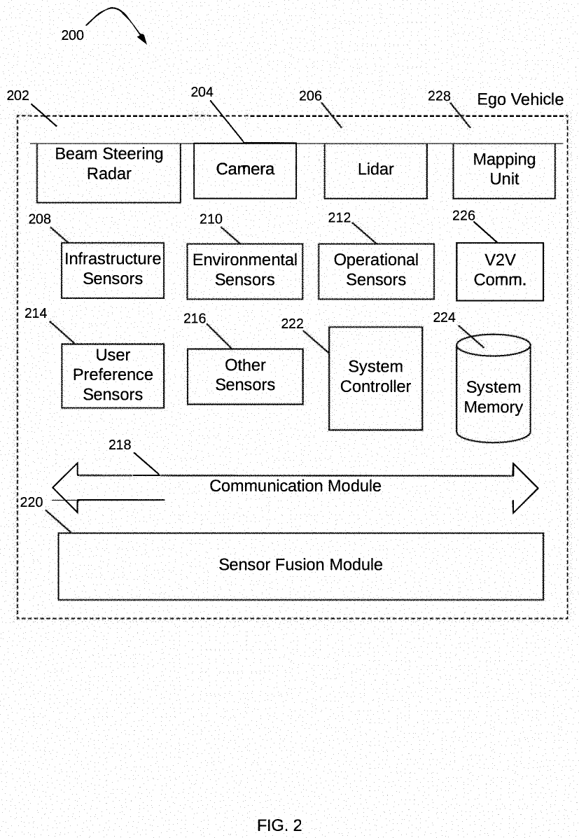

Attention is now directed to FIG. 2, which illustrates a schematic diagram of an autonomous driving system for an ego vehicle in accordance with various embodiments. Autonomous driving system 200 is a system for use in an ego vehicle that provides some or full automation of driving functions. The driving functions may include, for example, steering, accelerating, braking, and monitoring the surrounding environment and driving conditions to respond to events, such as changing lanes or speed when needed to avoid traffic, crossing pedestrians, animals, and so on. The autonomous driving system 200 includes a beam steering radar system 202 and other sensor systems, such as but not limited to camera 204, lidar 206, infrastructure sensors 208, environmental sensors 210, operational sensors 212, user preference sensors 214, and other sensors 216. Autonomous driving system 200 also includes a communications module 218, a sensor fusion module 220, a system controller 222, a system memory 224, a vehicle to vehicle (V2V) communications module 226, and a mapping unit 228. It is appreciated that this configuration of autonomous driving system 200 is an example configuration and not meant to be limiting to the specific structure illustrated in FIG. 2. Additional systems and modules not shown in FIG. 2 may be included in autonomous driving system 200.

In various examples, beam steering radar 202 includes at least one beam steering antenna for providing dynamically controllable and steerable beams that can focus on one or multiple portions of a 360° FoV of the vehicle. The beams radiated from the beam steering antenna are reflected back from objects in the vehicle's path and surrounding environment and received and processed by the radar 202 to detect and identify the objects. The beam steering radar 202 includes a perception module (not shown), but which may be implemented in software, hardware or firmware within system 200, trained to identify objects detected by sensors, such as the radar and other sensors, using machine learning techniques; this may also provide information used to control the sensors 208, 210, 212 and so forth to react to detected objects. For example, on identification of a pedestrian, the sensors will focus more on that area to get a better understanding of the movement of the pedestrian. On identification of a fast moving vehicle, the sensors will adjust to focus on the vehicle. On identification of a bridge or tunnel, additional sensors may be initiated to focus on the height of the object and so forth. The camera sensor 204 and lidar 206 may also be used to identify objects in the path and surrounding environment of the ego vehicle.

Infrastructure sensors 208 may provide information from infrastructure while driving, such as from a smart road configuration, bill board information, traffic alerts and indicators, including traffic lights, stop signs, traffic warnings, and so forth. Environmental sensors 210 detect various conditions outside, such as temperature, humidity, fog, visibility, precipitation, among others. Operational sensors 212 provide information about the functional operation of the vehicle. This may be tire pressure, fuel levels, brake wear, and so forth. The user preference sensors 214 may be configured to detect conditions that are part of a user preference. This may be temperature adjustments, smart window shading, etc. Other sensors 216 may include additional sensors for monitoring conditions in and around the vehicle.

In various examples, the sensor fusion module 220 optimizes these various functions to provide an approximately comprehensive view of the vehicle and environments. Many types of sensors may be controlled by the sensor fusion module 220. The present invention may be used with a variety of sensors and those described herein do not present an exhaustive list. Each design may implement any sensors, transducers, communication means and so forth that provide information to enhance and improve operation of the system 200. Sensor fusion 220 is then designed to integrate any subset or all of the sensor information and is not limited, as vehicle designers have a variety of uses and considerations. In some systems, accelerometers, tire pressure sensors, acceleration monitors, air quality monitors, humidity detectors, wind detectors, and a host of other types of sensors and monitors may provide information to the sensor fusion, which is tasked with interpreting this information and transforming this into actions and controls for operation of the vehicle. Such operation may be as simple as turning on the windshield wipers and as complex as determining a path to avoid a major collision. Given the role of the sensor fusion, it is clear that accurate and real time calibration is important. These sensors may coordinate with each other to share information and consider the impact of one control action on another system. As an example, where an environmental sensor indicates an icy road condition, this will change the interpretation of the velocity of a vehicle so that the sensor fusion detects a problem event at much lower speeds to accommodate for the impact of ice; for example, the ADAS may extend the blind spot range to allow for slippery conditions. In this example, cars approaching may need additional time to slow down when a vehicle changes lanes and the traditional 6 car lengths per mph rule may extend to 10 car lengths.

In one example, in a congested driving condition, a noise detection module (not shown) may identify that there are multiple radar signals that may interfere with the vehicle. This information may be used by a perception module in radar 202 to adjust the radar's scan parameters so as to avoid these other signals and minimize interference. The system 200 is intended to imitate a human driver and detect the same information. A human driver uses visual, audio, vibrational and experiential information to make decisions. When another vehicles horn is used, drivers in the vicinity take notice that someone is generating a warning signal. This noise detection enables the driver to take action. Similarly, if a siren is heard or a collision is heard, the human driver takes appropriate note and action. The system 200 is intended to consider all of this information as well.

In another example, the environmental sensor 210 may detect that the weather is changing, and visibility is decreasing. In this situation, the sensor fusion module 220 may determine to configure the other sensors to improve the ability of the vehicle to navigate in these new conditions. The configuration may include turning off camera or lidar sensors 204-206 or reducing the sampling rate of these visibility-based sensors. This effectively places reliance on the sensor(s) adapted for the current situation. In response, the perception module configures the radar 202 for these conditions as well. For example, the beam steering radar 202 may reduce the beam width to provide a more focused beam, and thus a finer sensing capability.

In various examples, the sensor fusion module 220 may send a direct control to radar 202 based on historical conditions and controls. The sensor fusion module 220 may also use some of the sensors within system 200 to act as feedback or calibration for the other sensors. In this way, an operational sensor 212 may provide feedback to the perception module and/or the sensor fusion module 220 to create templates, patterns and control scenarios. These are based on successful actions or may be based on poor results, where the sensor fusion module 220 learns from past actions.

Data from sensors 202-216 may be combined in the sensor fusion module 220 to improve the target detection and identification performance of autonomous driving system 200. The sensor fusion module 220 may itself be controlled by the system controller 222, which may also interact with and control other modules and systems in the vehicle. For example, the system controller 222 may be configured to turn any of the different sensors 202-216 on and off as desired, or provide instructions to the vehicle to stop upon identifying a driving hazard (e.g., deer, pedestrian, cyclist, or another vehicle suddenly appearing in the vehicle's path, flying debris, etc.)

All modules and systems in the autonomous driving system 200 can be configured to communicate with each other through the communication module 218. Autonomous driving system 200 also includes the system memory 224, which may store information and data (e.g., static and dynamic data) used for operation of the system 200 and the ego vehicle using the system 200. The V2V communications module 226 can be used for communication with other vehicles. The V2V communications may also include information from other vehicles that is invisible to the user, driver, or rider of the vehicle, and may help vehicles coordinate to avoid an accident.

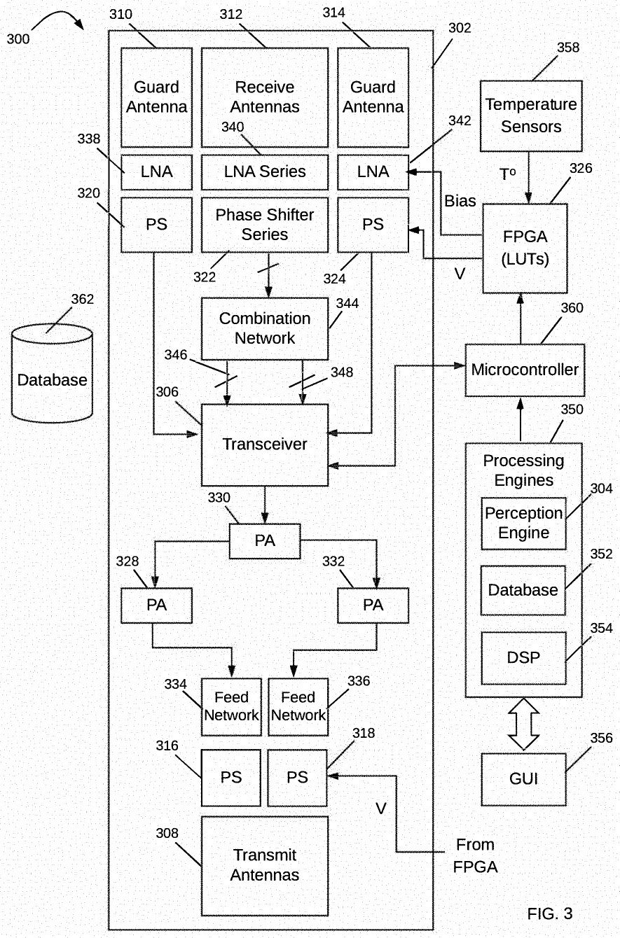

FIG. 3 illustrates a schematic diagram of a beam steering radar system in accordance with various examples. Beam steering radar 300 is a “digital eye” with true 3D vision and capable of a human-like interpretation of the world. The “digital eye” and human-like interpretation capabilities are provided by two main modules: radar module 302 and a perception engine 304. Radar module 302 is capable of both transmitting RF signals within a FoV and receiving the reflections of the transmitted signals as they reflect off of objects in the FoV. With the use of analog beamforming in radar module 302, a single transmit and receive chain can be used effectively to form a directional, as well as a steerable, beam.

As illustrated in FIG. 3, a transceiver 306 in the radar module 302 is adapted to generate signals for transmission through a series of transmit antennas 308 as well as manage signals received through a series of receive antennas 310, 312, 314. Beam steering within the FoV is implemented with phase shifter (“PS”) circuits 316, 318 coupled to the transmit antennas 308 on the transmit chain and phase shifter circuits 320, 322, 324 coupled to the receive antennas 310, 312, 314 on the receive chain, respectively. Careful real-time phase and amplitude calibration of transmit antennas 308 and receive antennas 310, 312, 314 can be performed with the use of couplers integrated into the radar module 302 as described in more detail below.

The use of phase shifter circuits 316, 318 and 320, 322, 324 enables separate control of the phase of each element in the transmit and receive antennas. Unlike early passive architectures, the beam is steerable not only to discrete angles but to any angle (i.e., from 0° to) 360° within the FoV using active beamforming antennas. A multiple element antenna can be used with an analog beamforming architecture where the individual antenna elements may be combined or divided at the port of the single transmit or receive chain without additional hardware components or individual digital processing for each antenna element. Further, the flexibility of multiple element antennas allows narrow beam width for transmit and receive. The antenna beam width decreases with an increase in the number of antenna elements. A narrow beam improves the directivity of the antenna and provides the beam steering radar 300 with a significantly longer detection range.

In accordance with various embodiments, the analog beam steering can be configured with phase shifters to operate at 77 GHz. Phase shifter circuits 316, 318 and 320, 322, 324 can be configured with a reflective phase shifter circuitry and can be implemented with a distributed varactor network. In some embodiments, the distributed varactor network can be built using GaAs materials. Each phase shifter circuit 316, 318 and 320, 322, 324 has a series of phase shifters, with each phase shifter coupled to an antenna element to generate a phase shift value of anywhere from 0° to 360° for signals transmitted or received by the antenna element. In some embodiments, the phase shifter circuitry can be built using SiGe and CMOS. Depending on the materials used, design specificity and level of implementation, cost of the phase shifters can be a factor to meet specific demands of customer applications. In some implementations, each phase shifter circuit 316, 318 and 320, 322, 324 is controlled by a Field Programmable Gate Array (“FPGA”) 326, which provides a series of voltages to the phase shifters in each phase shifter circuit that results in a series of phase shifts.

In various examples, a voltage value is applied to each phase shifter in the phase shifter circuits 316, 318 and 320, 322, 324 to generate a given phase shift and provide beam steering. The voltages applied to the phase shifters in phase shifter circuits 316, 318 and 320, 322, 324 are stored in Look-up Tables (“LUTs”) in the FPGA 326. These LUTs are generated by an antenna calibration process that determines which voltages to apply to each phase shifter to generate a given phase shift under each operating condition. In some implementations, the phase shifters in phase shifter circuits 316, 318 and 320, 322, 324 are capable of generating phase shifts at a very high resolution, for example, of less than two degrees, less than one degree, less than 0.5 degree, or less than 0.25 degree. This enhanced control over the phase allows the transmit and receive antennas in radar module 302 to steer beams with a very small step size, improving the capability of the beam steering radar 300 to resolve closely located targets at a small angular resolution.

In various examples, the transmit antennas 308 and the receive antennas 310, 312, 314 may be a meta-structure antenna, a phase array antenna, or any other antenna capable of radiating RF signals in millimeter wave frequencies as required for automotive applications. These concepts and inventions may also apply to other frequencies, however, the automotive example is provided in this description for clarity of understanding.

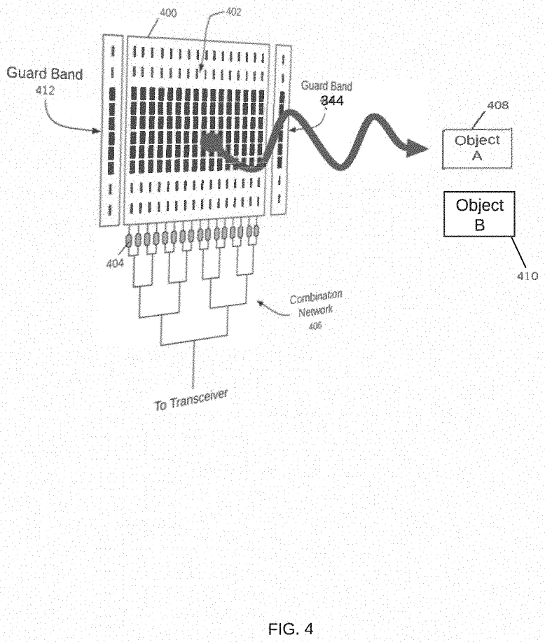

A meta-structure, as generally defined herein, is an engineered structure capable of controlling and manipulating incident radiation at a desired direction based on its geometry. Various configurations, shapes, designs and dimensions of the antennas 308, 310, 312, 314 may be used to implement specific designs and meet specific constraints in an antenna system, such as antenna 400 shown in FIG. 4.

In accordance with various embodiments, the transmit chain in beam steering radar 300 starts with the transceiver 306 generating RF signals to prepare for transmission over-the-air by the transmit antennas 308. The RF signals may be, for example, Frequency-Modulated Continuous Wave (“FMCW”) signals. An FMCW signal enables the beam steering radar 300 to determine both the distance to an object (range) and the object's velocity by measuring the differences in phase or frequency between the transmitted signals and the received/reflected signals or echoes. Within FMCW formats, there are a variety of waveform patterns that may be used, including sinusoidal, triangular, sawtooth, rectangular and so forth, each having advantages and purposes.

Once the FMCW signals are generated by the transceiver 306, they are provided to power amplifiers (“PAs”) 328, 330, 332. Signal amplification is needed for the FMCW signals to reach the long ranges desired for object detection, as the signals attenuate as they radiate by the transmit antennas 308. From the power amplifiers 328, 330, 332, the signals are divided and distributed through feed networks 334, 336, which form a power divider system to divide an input signal into multiple signals, one for each element of the transmit antennas 308. The feed networks 334, 336 may divide the signals so power is equally distributed among them or alternatively, so power is distributed according to another scheme, in which the divided signals do not all receive the same power. Each signal from the feed networks 334, 336 is then input into a phase shifter in phase shifter circuits 316, 318, where they are phase shifted based on voltages generated by the FPGA 326 under the direction of microcontroller 360 and then transmitted through transmit antennas 308.

Microcontroller 360 is configured to determine which phase shifts to apply to the phase shifters in phase shifter circuits 316, 318 according to a desired scanning mode based on road and environmental scenarios. Microcontroller 360 is also configured to determine the scan parameters for the transceiver 306 to apply at its next scan. The scan parameters may be determined at the direction of one of the processing engines 350, such as at the direction of perception engine 304. Depending on the objects detected, the perception engine 304 may be configured to instruct the microcontroller 360 to adjust the scan parameters at a next scan to focus on a given area of the FoV or to steer the beams to a different direction.

In various examples and as described in more detail below, the beam steering radar 300 can be configured to operate in one of various modes, including but not limited to a full scanning mode and a selective scanning mode. In a full scanning mode, both transmit antennas 308 and receive antennas 312 scan a complete FoV with small incremental steps. Even though the FoV may be limited by system parameters due to increased side lobes as a function of the steering angle, the beam steering radar 300 is able to detect objects over a significant area for a long range radar. The range of angles to be scanned on either side of boresight as well as the step size between steering angles/phase shifts can be dynamically varied based on the driving environment. To improve performance of an autonomous vehicle (e.g., an ego vehicle) driving through an urban environment, the scan range can be increased to keep monitoring the intersections and curbs to detect vehicles, pedestrians or bicyclists. This wide scan range may deteriorate the frame rate (revisit rate) but is considered acceptable as the urban environment generally involves low velocity driving scenarios. For a high-speed freeway scenario, where the frame rate is critical, a higher frame rate can be maintained by reducing the scan range. In this case, a few degrees of beam scanning on either side of the boresight would suffice for long-range target detection and tracking.

In a selective scanning mode, the beam steering radar 300 can be configured to scan around an area of interest by steering to a desired angle and then scanning around that angle. This ensures the beam steering radar 300 can detect objects in the area of interest without wasting any processing or scanning cycles illuminating areas with no valid objects. Since the beam steering radar 300 is capable of detecting objects at a long distance, e.g., 300 m or more at boresight, if there is a curve in a road, direct measures do not provide helpful information. Rather, the beam steering radar 300 can be figured to steer along the curvature of the road and aligns its beams towards the area of interest. In various examples, the selective scanning mode may be implemented by changing the chirp slope of the FMCW signals generated by the transceiver 306 and by shifting the phase of the transmitted signals to the steering angles needed to cover the curvature of the road.

In some implementations, objects can be detected with the beam steering radar 300 by reflections or echoes that are received at the series of receive antennas 310, 312, 314, which are directed by phase shifter circuits 320-324. Low noise amplifiers (“LNAs) 338, 340, 342 are positioned between receive antennas 310,312, 314 and phase shifter circuits 320, 322, 324, which include phase shifters similar to the phase shifters in phase shifter circuits 316-318. For receive operation, phase shifter circuits 320, 322, 324 create phase differentials between radiating elements in the receive antennas 310, 312, 314 to compensate for the time delay of received signals between radiating elements due to spatial configurations. Receive phase-shifting, also referred to as analog beamforming, combines the received signals for aligning echoes to identify the location, or position of a detected object. That is, phase shifting aligns the received signals that arrive at different times at each of the radiating elements in receive antennas 310, 312, 314. Similar to phase shifters circuits 316, 318 on the transmit chain, phase shifter circuits 320, 322, 324 are controlled by FPGA 326, which provides the voltages to each phase shifter to generate the desired phase shift. FPGA 326 also provides bias voltages to the low noise amplifiers 338, 340, 342.

The receive chain then combines the signals received at receive antennas 312 at combination network 344, from which the combined signals propagate to the transceiver 306. In some implementations, as illustrated in FIG. 3, the combination network 344 generates two combined signals 346, 348, with each signal combining signals from a number of elements in the receive antennas 312. In some embodiments, the receive antennas 312 include 48 radiating elements, each receiving an electromagnetic signal. These are processed in the analog domain by a set of LNAs 340 and a set of phase shifters 322. In the present embodiment, each element is a radiating element coupled to an LNA and then to a phase shifter. In this way, there are 48 output signals from phase shifter module 322. The combination network divides this into two signals. Each of the signals 346, 348 is a combination of signals received at the combination network 344, specifically 24 signals are combined to form signal 346, and the other 24 signals (from the original signals received at the 48 elements) are combined to form signal 348. In some embodiments, the receive antenna 312 may include 8, 16, 24, or 32 elements and so on, depending on the desired configuration. The higher the number of antenna elements, the narrower the beam width.

In some implementations, the signals received at receive antennas 310 and 314 go directly from phase shifter circuits 320 and 324 to the transceiver 306. Receive antennas 310 and 314 are guard antennas that generate a radiation pattern separate from the main beams received by the 48-element receive antenna 312. In some embodiments, the guard antennas 310 and 314 are implemented to effectively eliminate side-lobe returns from objects. The goal is for the guard antennas 310 and 314 to provide a gain that is higher than the side lobes, and therefore enable elimination of the side-lobes or reduce their presence significantly. Guard antennas 310 and 314 effectively act as a side lobe filter.

Once the received signals are received by transceiver 306, they are processed by one or more processing engines 350. The processing engines 350 include the perception engine 304 which detects and identifies objects in the received signal with neural network and artificial intelligence techniques, database 352 to store historical and other information for the beam steering radar 300, and a digital signal processing (“DSP”) engine 354 with an analog-to-digital converter (“ADC”) module to convert the analog signals from transceiver 306 into digital signals that can be processed to determine angles of arrival and other valuable information for the detection and identification of objects by perception engine 304. In one or more implementations, the DSP engine 354 may be integrated with the microcontroller 360 or the transceiver 306.

The beam steering radar 300 also includes a graphical user interface (“GUI”) 356 to enable configuration of scan parameters such as the total angle of the scanned area defining the FoV, the beam width or the scan angle of each incremental transmission beam, the number of chirps in the radar signal, the chirp time, the chirp slope, the chirp segment time, and so on as desired. In addition, the beam steering radar 300 has a temperature sensor 358 for sensing the temperature around the vehicle so that the proper voltages from FPGA 326 may be used to generate the desired phase shifts. The voltages stored in FPGA 326 are determined during calibration of the antennas under different operating conditions, including temperature conditions. The database 362 may also be used in the beam steering radar 300 to store radar and other useful data.

Attention is now directed to FIG. 4, which shows the antenna elements of the receive and guard antennas, similar to those illustrated in FIG. 3 in more detail. Receive antenna 400 has a number of radiating elements 402 creating receive paths for signals or reflections from an object at a slightly different time. In various implementations, the radiating elements 402 are meta-structures or patches in an array configuration such as in a 48-element antenna, a 24-element antenna, or 96-element antenna. The phase and amplification modules 404 provide phase shifting to align the signals in time. The radiating elements 402 are coupled to the combination network 406 and to phase and amplification modules 404, including for example, but limited to phase shifters and low noise amplifiers that are implemented for example, as phase shifter circuits 320, 322, 324 and low noise amplifiers 338, 340, 342 as shown in FIG. 3. In the present illustration, two objects, object A 408 and object B 410, are located at a same range and having a same velocity with respect to the antenna 400. When the distance between the objects is less than the bandwidth of a radiation beam, the objects may be indistinguishable by the system. This is referred to as angular resolution or spatial resolution. In the radar and object detection fields, the angular resolution describes the radar's ability to distinguish between objects positioned proximate each other, wherein proximate location is generally measured by the range from an object detection mechanism, such as a radar antenna, to the objects and the velocity of the objects.

Radar angular resolution is the minimum distance between two equally large targets at the same range which the radar is able to distinguish and separate. The angular resolution is a function of the antenna's half-power beam width, referred to as the 3 dB beam width and serves as limiting factor to object differentiation. Distinguishing objects is based on accurately identifying the angle of arrival of reflections from the objects. Smaller beam width angles result in high directivity and more refined angular resolution but requires faster scanning to achieve the smaller step sizes. For example, in autonomous vehicle applications, the radar is tasked with scanning an environment of the vehicle within a sufficient time period for the vehicle to take corrective action when needed. This limits the capability of a system to specific steps. This means that any object having a distance therebetween less than the 3 dB angle beam width cannot be distinguished without additional processing. Put another way, two identical targets at the same distance are resolved in angle if they are separated by more than the antenna 3 dB beam width. The present examples use the multiple guard band antennas 412, 414 to distinguish between the objects.

Calibration of the receive antenna 400 is necessary to ensure that the antenna will have the gain and phase expected from the phase and amplification modules 404. The goal of antenna calibration is to determine any phase and amplitude corrections that need to be performed in the radar module to guarantee its expected performance. As the phase and amplitude of the receive antenna 400 may be affected by manufacturing, hardware, temperature, environmental, and other issues as a result of being integrated in a radar module, it is imperative that calibration be performed while the antenna is integrated with the module. Further, as these and other issues may occur during operation of the radar module, it is also imperative that calibration be performed in real-time and without disrupting the signal flow in the radar module.

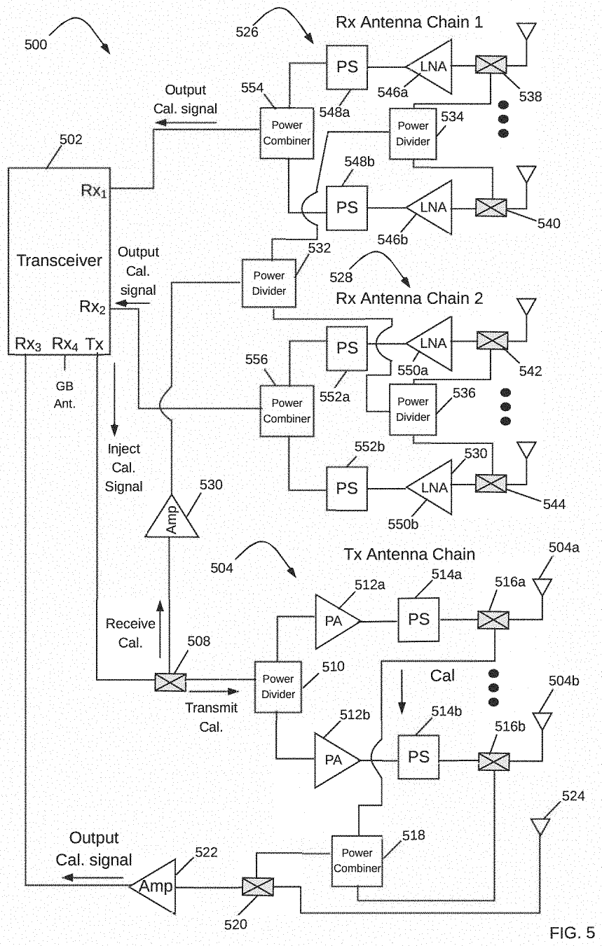

Accordingly, real-time phase and amplitude calibration of the receive and transmit antennas in radar module 300 is implemented with the use of strategically placed couplers in the radar module. FIG. 5 shows an example schematic diagram for real-time calibration of transmit and receive antennas in the radar module of FIG. 3. Real-time calibration is performed by taking advantage of the existing circuitry/hardware in the radar module 500. Transceiver 502 injects a calibration signal into the transmit and receive antennas and the signal is read back through the transmit and receive processing chains with the use of calibration couplers, power dividers/combiners and amplifiers. In various implementations, the calibration signal (e.g., a continuous waveform indicated by the arrow out of the transmit port in transceiver 502) is of a frequency different than the operating frequency of the radar module 500. In some implementations, the calibration signal can be at the same frequency as an encoded signal. Calibration of the transmit and receive antennas to correct for any phase and/or amplitude variations is performed while the radar module 500 is in operation.

Calibration of the transmit antennas 504a-b (also collectively referred to herein as antennas 504) is performed by injecting the calibration signal into coupler 508 connected to power divider 510. The signal is uniformly divided for amplification at power amplifiers 512a-b and phase shifting at phase shifters 514a-b, respectively. The divided and phase shifted calibration signals are received at couplers 516a-b, combined at power combiner 518 and sent to coupler 520 and amplifier 522 (which may be power amplifier, a low noise amplifier or any other amplifier) before reaching a receive port in the transceiver 502 that is used for guard band antenna 524. The use of coupler 520 in the path of the guard band antenna 524 enables the output calibration signal to be sent directly to the transceiver 502 for processing. Notice that this allows transceiver 502 to calibrate antennas while the radar module 500 is in operation, requiring coordination of when and how to inject a calibration signal in the transmit port instead of an FMCW signal that is used in the normal radar operation to detect objects. Such coordination may be performed by the transceiver 502 itself or by one of the processing engines connected to transceiver 502 (e.g., processing engines 350 of FIG. 3).

Likewise, the calibration of receive antennas 526 (receive antenna chain 1) and 528 (receive antenna chain 2) to correct for any phase and/or amplitude variations is performed in real-time while the radar module 500 is in operation, i.e., while the radar module is receiving reflections from objects at its operating frequency, e.g., 77 GHz. In one example, each receive antenna 526, 528 is a 24-element antenna to form a 48-element array. In various implementations, a calibration signal (e.g., a continuous waveform) is input into coupler 508, just as in the case of calibration of transmit antennas 504a-b. This time, however, instead of sending the calibration signal through the transmit antennas 504 via power divider 510, the signal is directed by coupler 508 to the receive antennas 526, 528 via the amplifier 530.

The calibration signal is then uniformly divided at power divider 532 to reach each one of the receive antennas 526, 528 via power divider 534 in receive antenna 526 and power divider 536 in receive antenna 528. The power dividers 534 and 536 uniformly divide the signal to reach a set of couplers: couplers 538, 540 in receive antenna 526 and couplers 542, 544 in receive antenna 528. In alternate embodiments the power dividers may employ non-uniform division to achieve a specific beamforming pattern. Couplers 538, 540, 542, 544 are passive elements that inject the calibration signal into the receive antennas 526, 528. During operation of the receive antenna 526, the calibration signal is sampled at the couplers 538, 540, amplified at the low noise amplifiers 546a-b, phase shifted at the phase shifters 548a-b, combined at power combiner 554, and read back through the receive port Rₓ₁. Similarly, during operation of the receive antenna 528, the calibration signal is sampled at the couplers 542-544, amplified at the low noise amplifiers 550a-b, phase shifted at the phase shifters 552a-b, combined at power combiner 556, and read back through the receive port Rₓ₂.

In some implementations, calibration of the transmit antennas 504 and receive antennas 526, 528 can be performed element-by-element by activating a single phase shifter or low noise amplifier at a time, while the others are not active and matched to proper termination. In some embodiments, the antenna may be calibrated by activating multiple elements at a time. As the calibration is performed in real-time, the activation of the phase shifters and/or LNAs is dependent on the operation of the antennas 504 and 526, 528. Control of the calibration process may be implemented in a microcontroller, such as microcontroller 360 of FIG. 3, which can be configured to determine which phase shifts to apply to the phase shifters 514a-b, 548a-b, and 552a-b during operation of the radar module 500. In some implementations, the calibration is performed with the existing radar module hardware, with the addition of the various couplers, power dividers/combiners and amplifiers for propagation of calibration signals through the antennas. Variations in the arrangement and type of the couplers and other components illustrated may be made without departing from the scope of the claims set forth herein. Additional components, different components, or fewer components may be provided.

In accordance with various embodiments, a system for real-time calibration of a phased array antenna integrated in a beam steering radar is provided. The system includes a transceiver configured for injecting an injected signal to the phased array antenna, a transmit antenna configured for generating a phase shifted and amplified signal from the injected signal, a receive antenna configured for transmitting the phase shifted and amplified signal to the transceiver for measurement, and a plurality of couplers configured for receiving the calibration signal from the transceiver and transmitting the phase shifted and amplified signal to the transceiver.

In some embodiments, the injected signal is transmitted at a frequency different than a frequency of operation of the beam steering radar. In some embodiments, the plurality of couplers is connected to a plurality of amplifiers and phase shifters in the phased array antenna. In some embodiments, the system further includes a plurality of power dividers each configured for dividing the injected signal from the transceiver. In some embodiments, each power divider is connected to at least two transmit amplifiers for amplification of the divided injected signal and at least two phase shifters for phase shifting of the divided injected signal.

In some embodiments, the system further includes a plurality of power combiners each configured for combining the phase shifted and amplified signal from the plurality of couplers, each power combiner connected to the transceiver for transmitting the phase shifted and amplified signal from the plurality of couplers to a receive port of the transceiver. In some embodiments, each power divider is connected to the plurality of couplers for transmitting the injected signal from the power divider to a plurality of low noise amplifiers.

In some embodiments, the system further includes a plurality of power combiners each configured for combining the phase shifted and amplified signal, the power combiner connected to the transceiver for transmitting the phase shifted and amplified signal from the plurality of low noise amplifiers to a receive port of the transceiver.

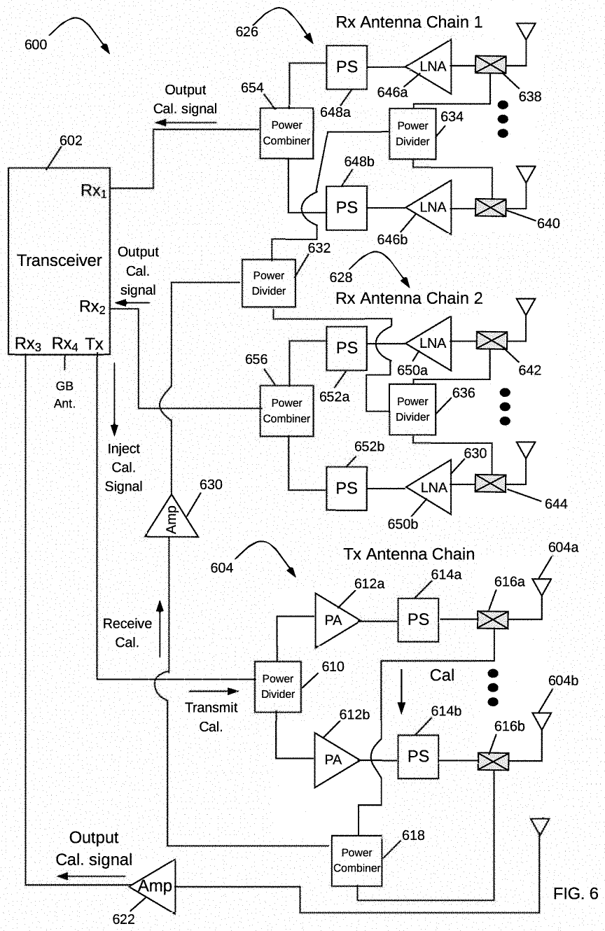

A variation of the real-time calibration illustrated in FIG. 5 is shown in FIG. 6. In this implementation, a calibration path between receive antennas 626 and 628 and transmit antenna 604 (including 604a-b) is created with all the components in radar module 600 in a calibration loop. A calibration signal is injected by the transceiver 602, passing through power divider 610 to power amplifiers 612a-b and phase shifters 614a-b before being sampled at couplers 616a-b. The couplers 616a-b can be configured to sense the calibration signals and the signals are combined at power combiner 618. The combined signal is then amplified at amplifier 630 and divided at power divider 632 to reach the couplers 638, 640, 642, 644.

The couplers 638, 640, 642, 644 will then inject the calibration signals back in the receive antenna network to pass through low noise amplifiers 646a-b and 650a-b, and phase shifters 648a-b and 652a-b before being combined at power combiners 654 and 656 and received by the transceiver 602 at Rₓ₁ and Rₓ₂, respectively. In some implementations, while objects for detection are in the main path between the transmit antenna output and the receive antenna input, a calibration path between the transmit and receive networks is also created in this implementation. The calibration path can be controlled and used for real-time calibration and advantageously, the contribution of the components in radar module 600 can be controlled to calibrate specific components.

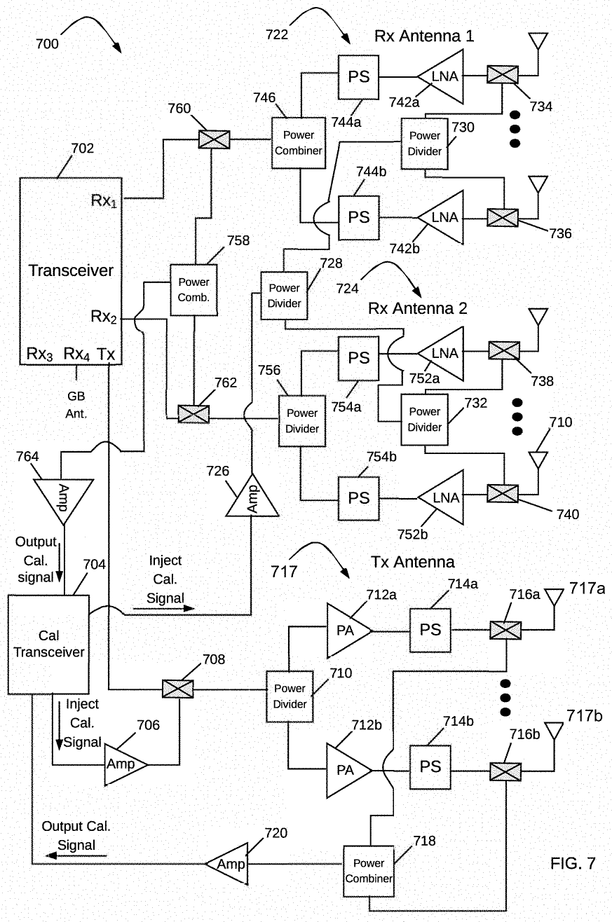

Another implementation for real-time calibration of transmit and receive antennas is shown in FIG. 7. In this implementation, radar module 700 has two transceivers: transceiver 702 dedicated to the normal radar operation of transmitting RF signals and receiving their reflections to detect and identify objects, and transceiver 704 dedicated to calibration. The two transceivers work in tandem, with calibration transceiver 704 injecting calibration signals in the transmit and receive antennas and receiving their returns to correct for any phase and/or amplitude variations in the antennas. In various examples, the calibration transceiver 704 may operate in alternate time windows from transceiver 702. A microcontroller such as microcontroller 360 of FIG. 3, may control the timing of the calibration transceiver 704.

Calibration of the transmit antennas 704 is performed by injecting a calibration signal into amplifier 706 and coupler 708 connected to power divider 710. The signal is uniformly divided for amplification at phase amplifiers 712a-b and phase shifting at phase shifters 714a-b. The divided and phase shifted calibration signals are received and sampled at couplers 716a-b, combined at power combiner 718 and sent to amplifier 720 before reaching the calibration transceiver 704 for processing, i.e., for determining any phase and/or amplitude corrections that need to be performed for the antennas 717a-b for transmit antenna 717.

Likewise, the calibration of receive antennas 722 and 724 is performed by having the calibration transceiver 704 inject a calibration signal into amplifier 726 to be uniformly divided at power divider 728. The calibration signal is then sent to each one of the receive antennas 722, 724 via power divider 730 in receive antenna 722 and power divider 732 in receive antenna 724. The power dividers 730 and 732 uniformly divide the signal to reach a set of couplers: couplers 734, 736 in receive antenna 722 and couplers 738, 740 in receive antenna 724. During operation of the receive antenna 722, the calibration signal is sampled at the couplers 734, 736, amplified at the low noise amplifiers 742a-b, phase shifted at the phase shifters 744a-b and combined at power combiner 746. Similarly, during operation of the receive antenna 724, the calibration signal is sampled at the couplers 738, 740, amplified at the low noise amplifiers 752a-b, phase shifted at the phase shifters 754a-b and combined at power combiner 756. The output calibration signals from power combiners 746 and 756 are then combined at power combiner 758 via couplers 760 and 762, which also serve the dual purpose of sending received signals to the receive ports Rₓ₁ and Rₓ₂ at the transceiver 702. Lastly, the output calibration signal is amplified at amplifier 764 before it is sent to calibration transceiver 704 for processing.

Similar to the real-time calibration performed in radar modules 500 and 600, the real-time calibration in radar module 700 can be performed element-by-element by activating a single phase shifter or low noise amplifier at a time, while the others are not active and matched to proper termination. In other examples, the antennas may be calibrated by activating multiple elements at a time. Variations in the arrangement and type of the couplers and other components illustrated may be made without departing from the scope of the claims set forth herein. Additional components, different components, or fewer components may be provided.

In accordance with various embodiments, a system for real-time calibration of a phased array antenna integrated in a beam steering radar is provided. The system includes a calibration unit for injecting a calibration signal to the phased array antenna during operation of the beam steering radar. The calibration signal transmits at a frequency different than a frequency of operation of the beam steering radar. The system also includes a plurality of transmit calibration couplers for receiving the injected signal, the transmit calibration couplers connected to a plurality of amplifiers and phase shifters in the phased array antenna to generate a phase shifted and amplified signal. The system includes a plurality of receive calibration couplers connected to the plurality of phase shifters for transmitting the phase shifted and amplified signal to the calibration unit for measurement.

In some embodiments, the system further includes a power divider configured for dividing the calibration signal from the calibration unit. In some implementations, the power divider is connected to a plurality of transmit amplifiers for amplification of the calibration signal and a plurality of phase shifters for phase shifting of the calibration signal. In some implementations, the system further includes a power combiner configured for combining the phase shifted and amplified signal from the plurality of transmit calibration couplers, the power combiner connected to the calibration unit for transmitting the phase shifted and amplified signal from the plurality of transmit calibration couplers to a receive port of the calibration unit.

In some embodiments, the power divider is connected to the plurality of receive calibration couplers for transmitting the calibration signal from the power divider to a plurality of low noise amplifiers. In some implementations, the system further includes a power combiner configured for combining the phase shifted and amplified signal, the power combiner connected to the calibration unit for transmitting the phase shifted and amplified signal from the plurality of low noise amplifiers to a receive port of the calibration unit.

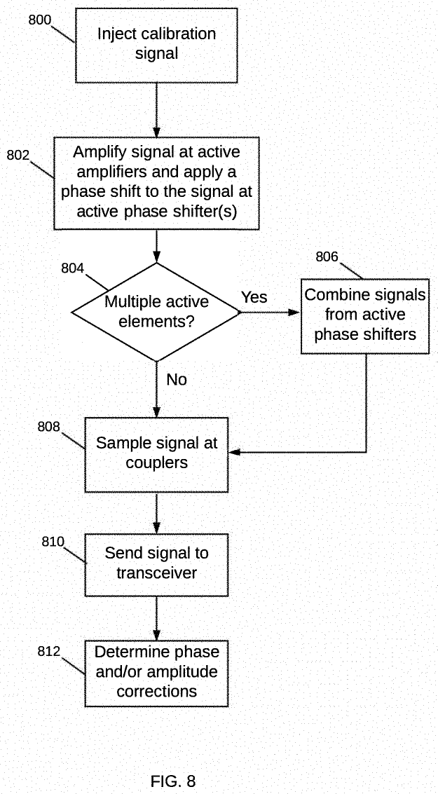

The real-time calibration process for a transmit or receive antenna is shown in FIG. 8. First, an RF calibration signal is injected in the antenna, either transmit or receive antennas (800). The antenna has multiple elements in a phased array configuration and the calibration process may be performed element-by-element or with multiple elements at once. During element-by-element calibration, a single element is active at a time. Accordingly, the received signal is amplified at the active amplifier(s) connected to the active antenna element(s) and phase shifted at the active phase shifter(s) connected to the active amplifier(s) (802). The phase shifted signals are then combined at a power combiner if needed (804-806) to generate a signal that is sent to a coupler(s) (808). The signal from the coupler(s) is sampled and output to a transceiver for processing (810) to determine the operating characteristic of the active antenna element(s). The transceiver may either be the existing transceiver in the radar module or a dedicated calibration transceiver, as shown in FIG. 7. Any corrections in phase or magnitude are determined at the transceiver (812) to ensure the antenna being calibrated will operate as accurately as expected and without any variations in phase and gain.

In some implementations, this real-time calibration process is the same whether the antenna is a transmit, guard band or receive antenna. A calibration signal is injected into couplers in the antenna and read back through the antenna and radar module circuitry into the transceiver. Any adjustments to phase and/or amplitude that need to be performed can be done via the microcontroller in the radar module. As described herein, the subject technology provides advantages over the convention calibration approaches by enabling calibration of a phased array antenna built-in a complex radar module while the radar module is in operation. This enables accurate beam steering performance of the radar module at any steering angle.

In accordance with various embodiments, a method to calibrate a phased array antenna integrated in a beam steering radar is provided. The method includes injecting a calibration signal at a plurality of transmit calibration couplers in the phased array antenna during operation of the beam steering radar, the calibration signal at a frequency different than a frequency of operation of the beam steering radar, applying a phase shift to the calibration signal with an active phase shifter, generating a phase shifted signal based on the phase shift, sampling the phase shifted signal at a receive calibration coupler, generating an output signal based on the sampling of the phase shifted signal, measuring the output signal, and determining a phase correction for the phased array receive antenna based on measured output signal.

In some embodiments, prior to application of the phase shift, the method further includes amplifying the calibration signal with a power amplifier or a low noise amplifier, and generating an amplified signal based on the calibration signal. In some embodiments, the method further includes sampling the amplified signal based on the amplified signal, determining an amplitude correction for the phased array receive antenna based on sampled amplified signal.

In some embodiments, the output signal is a first output signal, the measured output signal is a first measured output signal, and the phase correction is a first phase correction, the method further includes sampling the phase shifted signal at a transmit calibration coupler, generating a second output signal based on the sampling of the phase shifted signal, measuring the second output signal, and determining a second phase correction for the phased array transmit antenna based on the second measured output signal.

In some embodiments, the method further includes dividing the calibration signal with a power divider prior to application of the phase shift, and measuring output signals for each of divided calibration signals. In some embodiments, the method further includes combining measured output signals with a power combiner prior to determination of the phase correction. In some embodiments, the method further includes dividing the calibration signal with a power divider prior to amplification of the calibration signal, and measuring output signals for each of divided calibration signals. In some embodiments, the method further includes combining measured output signals with a power combiner prior to determination of the amplitude correction.

It is appreciated that the previous description of the disclosed examples is provided to enable any person skilled in the art to make or use the present disclosure. Various modifications to these examples will be readily apparent to those skilled in the art, and the generic principles defined herein may be applied to other examples without departing from the spirit or scope of the disclosure. Thus, the present disclosure is not intended to be limited to the examples shown herein but is to be accorded the widest scope consistent with the principles and novel features disclosed herein.

As used herein, the phrase “at least one of” preceding a series of items, with the terms “and” or “or” to separate any of the items, modifies the list as a whole, rather than each member of the list (i.e., each item). The phrase “at least one of” does not require selection of at least one item; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

Furthermore, to the extent that the term “include,” “have,” or the like is used in the description or the claims, such term is intended to be inclusive in a manner similar to the term “comprise” as “comprise” is interpreted when employed as a transitional word in a claim.

A reference to an element in the singular is not intended to mean “one and only one” unless specifically stated, but rather “one or more.” The term “some” refers to one or more. Underlined and/or italicized headings and subheadings are used for convenience only, do not limit the subject technology, and are not referred to in connection with the interpretation of the description of the subject technology. All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description.

While this specification contains many specifics, these should not be construed as limitations on the scope of what may be claimed, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable sub combination. Moreover, although features may be described above as acting in certain combinations and even initially claimed as such, one or more features from a claimed combination can in some cases be excised from the combination, and the claimed combination may be directed to a sub combination or variation of a sub combination.

The subject matter of this specification has been described in terms of particular aspects, but other aspects can be implemented and are within the scope of the following claims. For example, while operations are depicted in the drawings in a particular order, this should not be understood as requiring that such operations be performed in the particular order shown or in sequential order, or that all illustrated operations be performed, to achieve desirable results. The actions recited in the claims can be performed in a different order and still achieve desirable results. As one example, the processes depicted in the accompanying figures do not necessarily require the particular order shown, or sequential order, to achieve desirable results. Moreover, the separation of various system components in the aspects described above should not be understood as requiring such separation in all aspects, and it should be understood that the described program components and systems can generally be integrated together in a single hardware product or packaged into multiple hardware products. Other variations are within the scope of the following claim.

What is claimed is:

1. A system for real-time calibration of a phased array antenna integrated in a beam steering radar, comprising:
a calibration unit for injecting a calibration signal to the phased array antenna during operation of the beam steering radar, the calibration signal at a frequency different than a frequency of operation of the beam steering radar;
a plurality of transmit calibration couplers for receiving the injected calibration signal, the transmit calibration couplers connected to a plurality of amplifiers and phase shifters in the phased array antenna to generate a phase shifted and amplified signal; and
a plurality of receive calibration couplers connected to the plurality of phase shifters for transmitting the phase shifted and amplified signal to the calibration unit for measurement.

2. The system of claim 1, further comprising:
a power divider configured for dividing the calibration signal from the calibration unit.

3. The system of claim 2, wherein the power divider is connected to a plurality of transmit amplifiers for amplification of the calibration signal and a plurality of phase shifters for phase shifting of the calibration signal.

4. The system of claim 3, further comprising:
a power combiner configured for combining the phase shifted and amplified signal from the plurality of transmit calibration couplers, the power combiner connected to the calibration unit for transmitting the phase shifted and amplified signal from the plurality of transmit calibration couplers to a receive port of the calibration unit.

5. The system of claim 2, wherein the power divider is connected to the plurality of receive calibration couplers for transmitting the calibration signal from the power divider to a plurality of low noise amplifiers.

6. The system of claim 5, further comprising:
a power combiner configured for combining the phase shifted and amplified signal, the power combiner connected to the calibration unit for transmitting the phase shifted and amplified signal from the plurality of low noise amplifiers to a receive port of the calibration unit.

7. A system for real-time calibration of a phased array antenna integrated in a beam steering radar, comprising:
a transceiver configured for injecting a signal to the phased array antenna;
a transmit antenna configured for generating a phase shifted and amplified signal from the injected signal;
a receive antenna configured for transmitting the phase shifted and amplified signal to the transceiver for measurement; and
a plurality of couplers configured for receiving the calibration signal from the transceiver and transmitting the phase shifted and amplified signal to the transceiver.

8. The system of claim 7, wherein the injected signal is transmitted at a frequency different than a frequency of operation of the beam steering radar.

9. The system of claim 7, wherein the plurality of couplers is connected to a plurality of amplifiers and phase shifters in the phased array antenna.

10. The system of claim 7, further comprising:
a plurality of power dividers each configured for dividing the injected signal from the transceiver.

11. The system of claim 10, wherein each power divider is connected to at least two transmit amplifiers for amplification of the divided injected signal and at least two phase shifters for phase shifting of the divided injected signal.

12. The system of claim 11, further comprising:
a plurality of power combiners each configured for combining the phase shifted and amplified signal from the plurality of couplers, each power combiner connected to the transceiver for transmitting the phase shifted and amplified signal from the plurality of couplers to a receive port of the transceiver.

13. The system of claim 10, wherein each power divider is connected to the plurality of couplers for transmitting the injected signal from the power divider to a plurality of low noise amplifiers.

14. The system of claim 13, further comprising:
a plurality of power combiners each configured for combining the phase shifted and amplified signal, the power combiner connected to the transceiver for transmitting the phase shifted and amplified signal from the plurality of low noise amplifiers to a receive port of the transceiver.

15. A method to calibrate a phased array antenna integrated in a beam steering radar, comprising:
injecting a calibration signal at a plurality of transmit calibration couplers in the phased array antenna during operation of the beam steering radar, the calibration signal at a frequency different than a frequency of operation of the beam steering radar;
applying a phase shift to the calibration signal with an active phase shifter;
generating a phase shifted signal based on the phase shift;
sampling the phase shifted signal at a receive calibration coupler;
generating an output signal based on the sampling of the phase shifted signal;
measuring the output signal; and
determining a phase correction for the phased array receive antenna based on measured output signal.

16. The method of claim 15, wherein prior to application of the phase shift, the method further comprises:
amplifying the calibration signal with a power amplifier or a low noise amplifier; and
generating an amplified signal based on the calibration signal.

17. The method of claim 16, further comprising:
sampling the amplified signal based on the amplified signal; and
determining an amplitude correction for the phased array receive antenna based on sampled amplified signal.

18. The method of claim 15, wherein the output signal is a first output signal, the measured output signal is a first measured output signal, and the phase correction is a first phase correction, the method further comprising:
sampling the phase shifted signal at a transmit calibration coupler;
generating a second output signal based on the sampling of the phase shifted signal;
measuring the second output signal; and
determining a second phase correction for the phased array transmit antenna based on the second measured output signal.

19. The method of claim 15, further comprising:
dividing the calibration signal with a power divider prior to application of the phase shift; and
measuring output signals for each of divided calibration signals.

20. The method of claim 19, further comprising:
combining measured output signals with a power combiner prior to determination of the phase correction.

21. The method of claim 17, further comprising:
dividing the calibration signal with a power divider prior to amplification of the calibration signal; and
measuring output signals for each of divided calibration signals.

22. The method of claim 21, further comprising:
combining measured output signals with a power combiner prior to determination of the amplitude correction.
